(19) United States
(12) Patent Application Publication
(10) Pub. No.: US 2025/0357453 A1
(43) Pub. Date: Nov. 20, 2025

(54) Semiconductor Package

(71) Applicant: Samsung Electronics Co., Ltd., Suwon-si (KR)

(72) Inventor: Daewoong HEO, Suwon-si (KR)

(73) Assignee: Samsung Electronics Co., Ltd., Suwon-si (KR)

(21) Appl. No.: 19/082,469

(22) Filed: Mar. 18, 2025

(30) Foreign Application Priority Data
May 16, 2024 (KR) 10-2024-0064102

(51) Int. Cl. H01L 25/18; H01L 23/00; H01L 23/31; H01L 23/538; H10B 80/00; H10D 80/30

(52) U.S. Cl. CPC H01L 25/18; H01L 23/3135; H01L 23/3142; H01L 23/5383; H01L 24/45; H01L 24/48; H01L 24/32; H01L 24/85; H01L 2224/32145; H01L 2224/45005; H01L 2224/45015; H01L 2224/45124; H01L 2224/45144; H01L 2224/45147; H01L 2224/48227; H01L 2224/85181; H01L 2225/0651; H01L 2225/06562; H01L 2924/207; H10B 80/00; H10D 80/30

(57) ABSTRACT

A semiconductor package includes a redistribution wiring layer having redistribution wirings, a sealing member provided on the redistribution wiring layer and having a first surface in contact with the redistribution wiring layer and a second surface opposite to the first surface, a plurality of semiconductor chips sequentially stacked on one another within the sealing member and arranged such that a front surface on which chip pads each of the semiconductor chips are formed faces the redistribution wiring layer, a plurality of trenches extending in a vertical direction from the first surface of the sealing member to the front surfaces of the semiconductor chips and exposing the chip pads, a plurality of conductive wires extending in the vertical direction from the chip pads within the plurality of trenches and electrically connected to the redistribution wirings respectively, and filling members within the plurality of trenches and surrounding the conductive wires.

### CROSS-REFERENCE TO RELATED APPLICATION(S)

This application claims priority under 35 U.S.C. § 119 to Korean Patent Application No. 10-2024-0064102, filed on May 16, 2024 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a multi-chip package including a plurality of stacked chips and a method of manufacturing the same.

### 2. Description of the Related Art

In manufacturing a fan-out package using vertical wires, the vertical wires may be formed on chip pads of sequentially stacked semiconductor chips by a bonding wire process, and a molding member may be formed by a molding process to cover the semiconductor chips and the vertical wires. However, as demands for higher for higher integration increase, a wire diameter and pitch also decrease; therefore, there is a problem that wire sagging occurs due to the flow of the molding material during the molding process, resulting in a wire short defect.

### SUMMARY

Example embodiments provide a semiconductor package configured to prevent (or reduce) defects in a package manufacturing process and having improved bending characteristics.

Example embodiments provide a method of manufacturing the semiconductor package.

According to example embodiments, a semiconductor package includes a redistribution wiring layer having redistribution wirings; a sealing member on the redistribution wiring layer, the sealing member having a first surface in contact with the redistribution wiring layer and a second surface opposite to the first surface; a plurality of semiconductor chips within the sealing member; the plurality of semiconductor chips stacked such that a front surface of each of the semiconductor chips faces the redistribution wiring layer, the front surface of each of the semiconductor chips including chip pads; a plurality of trenches defined by the sealing member, the plurality of trenches extending in a vertical direction from the first surface of the sealing member to the front surfaces of the semiconductor chips such that the plurality of trenches expose the chip pads; a plurality of conductive wires within the plurality of trenches and extending in the vertical direction, the plurality of conductive wires electrically connecting the chip pads to the redistribution wirings; and filling members within the plurality of trenches and surrounding the conductive wires.

According to example embodiments, a semiconductor package includes a redistribution wiring layer having redistribution wirings; an encapsulation structure on the redistribution wiring layer; and outer connection members on an outer surface of the redistribution wiring layer, the outer connection members electrically connected to the redistribution wirings. The encapsulation structure includes a sealing member having a first surface in contact with the redistribution wiring layer and a second surface opposite to the first surface, a plurality of semiconductor chips within the sealing member, the plurality of semiconductor chips sequentially stacked such that a front surface of each of the plurality of semiconductor chips faces the redistribution wiring layer, the front surface of each of the semiconductor chips including chip pads, a plurality of trenches defined by the sealing member, the plurality of trenches extending in a vertical direction from the first surface of the sealing member to the front surfaces of the semiconductor chips such that plurality of trenches expose the chip pads, a plurality of conductive wires within the plurality of trenches and extending in the vertical direction, the plurality of conductive wires electrically connecting the chip pads to the redistribution wirings, and filling members within the plurality of trenches and surrounding the conductive wires.

According to example embodiments, a semiconductor package includes a redistribution wiring layer having redistribution wirings stacked in at least two layers and external connection members on an outer surface of the redistribution wiring layer, the external connection members electrically connected to the redistribution wirings; and an encapsulation structure stacked on the redistribution wiring layer, the encapsulation structure including a sealing member having a first surface in contact with the redistribution wiring layer and a second surface opposite to the first surface, a plurality of semiconductor chips within the sealing member, with a horizontal offset relative to each other the plurality of semiconductor chips sequentially stacked such that a front surface of each of the semiconductor chips faces the redistribution wiring layer, the front surface of each of the semiconductor chips including chip pads, a plurality of trenches defined by the sealing member, the plurality of trenches extending in a vertical direction from the first surface of the sealing member to the front surfaces of the semiconductor chips such that the plurality of trenches expose the chip pads, a plurality of conductive wires within the plurality of trenches and extending in the vertical direction, the plurality of conductive wires electrically connecting the chip pads to the redistribution wirings, and filling members within the plurality of trenches and surrounding the conductive wires.

According to example embodiments, a semiconductor package may include a redistribution wiring layer and an encapsulation structure stacked on the redistribution wiring layer. The encapsulation structure may include a sealing member, a plurality of semiconductor chips arranged within the sealing member, a plurality of trenches extending vertically from a first surface of the sealing member to front surfaces of the semiconductor chips and exposing the chip pads, conductive wires extending on the chip pads of the plurality of semiconductor chips within the plurality of trenches, and filling members within the plurality of trenches to surround the conducive wires.

After forming the molding member covering the semiconductor chips, the trenches may be formed in the molding member and the conductive wires may be formed within the trenches, so that wire sagging, a phenomenon in which wires are tilted due to the flow of a molding material during the molding process, may be prevented or mitigated. Further, the filling members that fill the trenches may have different properties from the sealing member, so that the mechanical behavior characteristics of the package may be improved.

### BRIEF DESCRIPTION OF THE DRAWINGS

Example embodiments will be more clearly understood from the following detailed description taken in conjunction with the accompanying drawings.

FIGS. 1 to 19 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a bottom view illustrating a sealing member of the semiconductor package in FIG. 1.

FIGS. 4 to 19 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings, wherein like reference numerals refer to like elements throughout. In this regard, the present embodiments may have different forms and should not be construed as being limited to the descriptions set forth herein.

Unless otherwise specified, in this specification, spatially relative terms such as ‘plan view,’ ‘upper’, ‘upper surface’, ‘lower’, ‘lower surface’, ‘side,’ ‘side surface’ and/or the like are based on the drawings, and in fact, depending on the direction in which the element is disposed, the terms may be modified. For example, the device may also be oriented in other ways (for example, turned over, and/or rotated 90 degrees and/or at other orientations), and the spatially relative terms used herein are to be interpreted accordingly.

When the terms “about” or “substantially” are used in this specification in connection with a numerical value, it is intended that the associated numerical value includes a manufacturing and/or operational tolerance (e.g., +10%) around the numerical value. Moreover, when the words “about” and “substantially” are used in connection with geometric shapes, it is intended that precision of the geometric shape is not required but that latitude for the shape is within the scope of the disclosure. Thus, while terms like “same,” identical,” or “equal” are used in description of the example embodiments, it should be understood that some imprecisions may exist. Thus, when one element or one numerical value is referred to as being the same as another element or equal to another numerical value, it should be understood that an element or a numerical value is the same as another element or another numerical value within the manufacturing and/or operational tolerance ranges (e.g., ±10%).

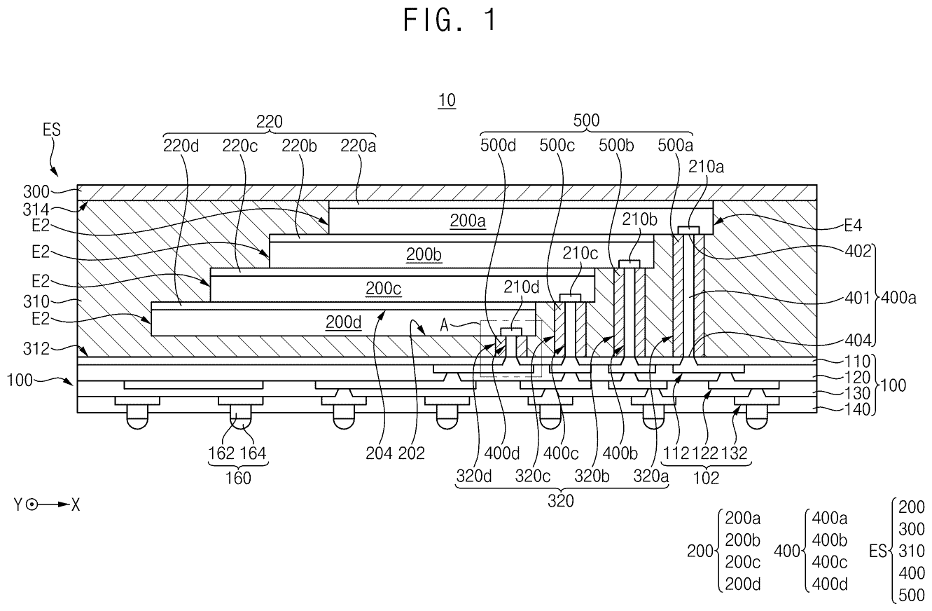

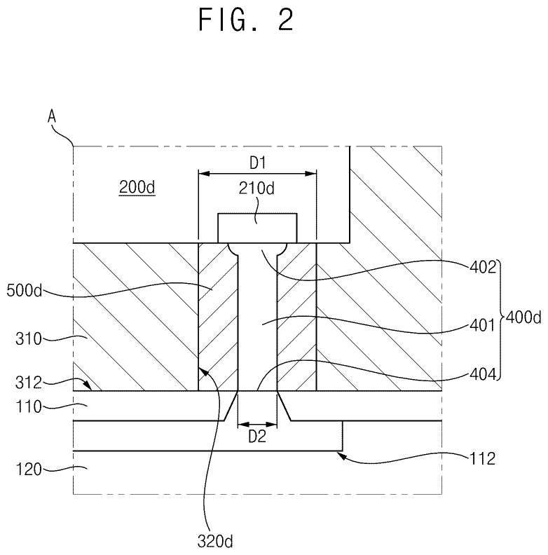

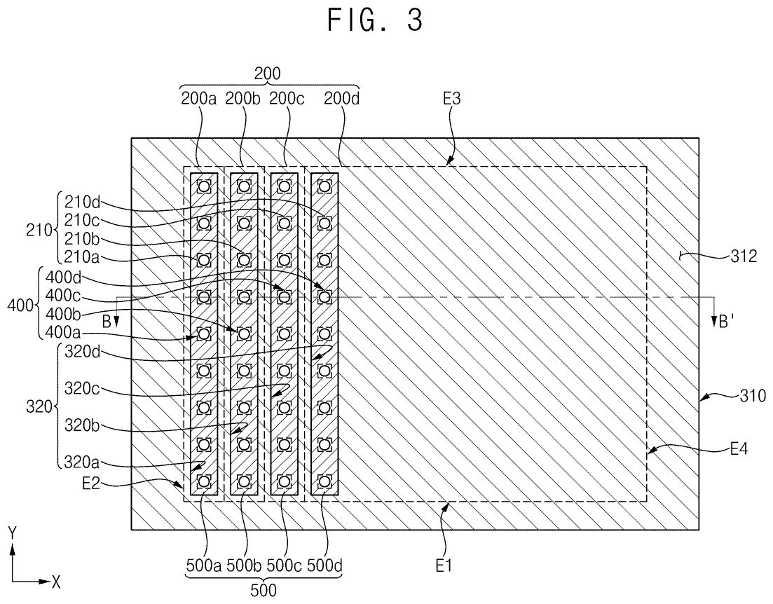

FIG. 1 is a cross-sectional view illustrating a semiconductor package in accordance with example embodiments. FIG. 2 is an enlarged cross-sectional view illustrating portion ‘A’ in FIG. 1. FIG. 3 is a bottom view illustrating a sealing member of the semiconductor package in FIG. 1. FIG. 1 includes a cross-section taken along the line B-B′ in FIG. 3.

Referring to FIGS. 1 to 3, a semiconductor package 10, according to some example embodiments, includes a redistribution wiring layer 100 and an encapsulation structure ES disposed on the redistribution wiring layer 100. Additionally, the semiconductor package 10 may further include external connection members 160 disposed on an outer surface of the redistribution wiring layer 100. The encapsulation structure ES may include a sealing member 310 having a first surface 312 and a second surface 314 opposite to the first surface 312, a plurality of semiconductor chips 200 disposed in the sealing member 310, a plurality of trenches 320 in the in the sealing member 310 and exposing chip pads 210 of the plurality of semiconductor chips 200, conductive wires 400 as a plurality of vertical conductive structures within the plurality of trenches 320 and extending from the chip pads 210 of the plurality of semiconductor chips 200, and filling members 500 in the plurality of trenches 320 and surrounding the conductive wires 400. Additionally, the encapsulation structure ES may further include a protective layer 300 disposed on the second surface 314 of the sealing member 310.

In example embodiments, the semiconductor package 10 may be a fan-out package in which the redistribution wiring layer 100 is formed to extend beyond a region where the semiconductor chip 200 are arranged. The redistribution wiring layer 100 may be formed by a wafer-level redistribution wiring process. In addition, the semiconductor package 10 may be provided as an upper package that is configured to be stacked on a lower package (not illustrated).

Additionally, the semiconductor package 10 may be provided as a System In Package (SIP). For example, one or more semiconductor chips may be disposed on the redistribution wiring layer 100. The semiconductor chips may include a logic chip (including a logic circuit) and/or a memory chip. The logic chip may be a controller that is configured to control memory chips. For example, the semiconductor chips may include a plurality of memory chips and a logic chip configured to control the chips. The memory chip may include various types of memory circuits, such as dynamic random access memory (DRAM), static random access memory (SRAM), flash, phase-change random access memory (PRAM), resistive random access memory (ReRAM), ferroelectric random access memory (FeRAM), magnetic random access memory (MRAM), etc.

In example embodiments, the redistribution wiring layer 100 may have redistribution wirings 102. The encapsulation structure ES may be configured such that the plurality of semiconductor chips 200 are electrically connected to the redistribution wirings 102 and such that the plurality of semiconductor chips 200 are stacked on the redistribution wiring layer 100. In such cases, the redistribution wiring layer 100 may be referred to as a front redistribution wiring layer (FRDL) of the fan-out package.

In particular, the redistribution wiring layer 100 may include a plurality of insulating layers (e.g., first, second, third and fourth lower insulating layers 110, 120, 130 and 140) and the redistribution wirings 102 provided in the first, second, third and fourth lower insulating layers. For example, the redistribution wirings 102 may include first, second and third redistribution wirings 112, 122 and 132. Additionally, though the redistribution wiring layer 100 is illustrated as including four lower insulating layers, the examples are not limited thereto. For example, the redistribution wiring layer 100 may include greater or fewer than four lower insulating layers.

The first, second, third and fourth lower insulating layers may include an insulator. The insulator may include, for example, a polymer, a dielectric layer, etc. For example, the first, second, third and fourth lower insulating layers may include a photosensitive insulating layer such as PID (photo imageable dielectric). The first, second, third and fourth lower insulating layers may be formed by a vapor deposition process, a spin coating process, etc. The redistribution wirings may include a conductor (e.g., a zero-band-gap material) such as aluminum (Al), copper (Cu), tin (Sn), nickel (Ni), gold (Au), platinum (Pt), an alloy thereof, and/or the like. The redistribution wirings may be formed by a plating process, an electroless plating process, a vapor deposition process, etc.

In particular, the first lower insulating layer 110 may be formed on the first surface 312 of the sealing member 310, and the first redistribution wirings 112 may be formed on the first lower insulating layer 110. The first redistribution wirings 112 may be electrically connected to the conductive wires 400 that are exposed from the first surface 312 of the sealing member 310, through first openings formed in the first lower insulating layer 120.

The second lower insulating layer 120 may be formed on the first lower insulating layer 110, and the second redistribution wirings 122 may be formed on the second lower insulating layer 120. The second redistribution wirings 122 may be electrically connected to the first redistribution wirings 112 through second openings formed in the second lower insulating layer 120.

The third lower insulating layer 130 may be formed on the second lower insulating layer 120, and the third redistribution wirings 132 may be formed on the third lower insulating layer 130. The third redistribution wirings 132 may be electrically connected to the second redistribution wirings 122 through third openings formed in the third lower insulating layer 130. As such, the redistribution wirings may facilitate electrical communication between the plurality of semiconductor chips 200 and the corresponding external connection members 160.

The fourth lower insulating layer 140 may be formed on the third lower insulating layer 130 to expose at least portions of the third redistribution wirings 132. The fourth lower insulating layer 140 may serve as a passivation layer.

It will be understood that the number, size, arrangement, etc. of the insulating layers and the redistribution wirings of the redistribution wiring layer are provided as an example, and the examples are not limited thereto.

In example embodiments, when viewed in a plan view, the redistribution wiring layer 100 may include a first region overlapping the semiconductor chips 200 of the encapsulation structure ES disposed on an upper surface of the redistribution wiring layer 100 and a second region surrounding the first region. The second region may be a fan-out region outside the region where the semiconductor chip is disposed.

In example embodiments, the encapsulation structure ES may include the sealing member 310 provided on the redistribution wiring layer 100. The first surface 312 of the sealing member 310 may be in contact with redistribution wiring layer 100. The encapsulation structure ES may further include the protective layer 300 on the second surface 314 of the sealing member 310.

The plurality of semiconductor chips 200 may be sequentially stacked and may be within the sealing member 310. The plurality of semiconductor chips 200 may be arranged such that a front surface 202 on which the chip pads 210 are formed faces the redistribution wiring layer 100. In example embodiments, each of the semiconductor chips 200 may have a rectangular shape with four sides when viewed in plan view. A first side surface E1 and a third side surface E3 of each of the semiconductor chips 200 may be arranged to be parallel to a first direction (X direction) and a second side surface E2 and a fourth side surface E4 of each of the semiconductor chips 200 may be arranged to be parallel to a second direction (Y direction) perpendicular to the first direction. The chip pads 210 may be disposed in a peripheral region along one side of each of the semiconductor chips 200.

In particular, the plurality of semiconductor chips 200 may include first, second, third, and fourth semiconductor chips 200a, 200b, 200c, and 200d stacked in a cascade structure from the protective layer 300. The first, second, third, and fourth semiconductor chips 200a, 200b, 200c, and 200d may be sequentially attached to a surface of the protective layer 300 using adhesive films 220. The adhesive films may include die attach film (DAF). For example, a thickness of the semiconductor chip may be within a range of 40 micrometers (μm) to 110 μm. The thickness of the adhesive film may be within a range of 10 μm to 60 μm.

The second semiconductor chip 200b may be offset aligned in a first horizontal direction (X direction) with respect to the first semiconductor chip 200a. The second semiconductor chip 200b may be offset aligned in the first horizontal direction such that the chip pads 210a of the first semiconductor chip 200a are exposed from the second semiconductor chip 200b. The third semiconductor chip 200c may be offset aligned in the first horizontal direction with respect to the second semiconductor chip 200b. The third semiconductor chip 200c may be offset aligned in the first horizontal direction such that the chip pads 210b of the second semiconductor chip 200b are exposed from the third semiconductor chip 200c. The fourth semiconductor chip 200d may be offset aligned in the first horizontal direction with respect to the third semiconductor chip 200c. The fourth semiconductor chip 200d may be offset aligned in the first horizontal direction such that the chip pads 210c of the third semiconductor chip 200c are exposed from the fourth semiconductor chip 200d.

As such, each of the first, second, and third semiconductor chips 200a, 200b, and 200c may have an overhang portion protruding from one side of each of the underlying second, third, and fourth semiconductor chips 200b, 200c, and 200d. When viewed from bottom view of FIG. 3, the chip pads 210a of the first semiconductor chip 200a may be arranged on a lower surface (that is, the front surface 202) of the overhang portion protruding from one side surface E2 of the second semiconductor chips 200b to be spaced apart from each other along a second horizontal direction (Y direction) perpendicular to the first horizontal direction. When viewed from bottom view, the chip pads 210b of the second semiconductor chip 200b may be arranged on a lower surface (that is, the front surface 202) of the overhang portion protruding from one side surface E2 of the third semiconductor chips 200c to be spaced apart from each other along the second horizontal direction. When viewed from bottom view, the chip pads 210c of the third semiconductor chip 200c may be arranged on a lower surface (that is, the front surface 202) of the overhang portion protruding from one side surface E2 of the fourth semiconductor chip 200d to be spaced apart from each other along the second horizontal direction.

The plurality of semiconductor chips 200 may include a memory chip including a memory circuits. For example, the semiconductor chip may include volatile memory devices such as SRAM devices and/or DRAM devices, and non-volatile memory devices such as flash memory devices, PRAM devices, MRAM devices or RRAM devices.

It will be understood that the number, size, arrangement, etc. of the semiconductor chips are provided as an example, and the examples not limited thereto. Also, although only a few chip pads are illustrated in the figures, it will be understood that the structure, shape, and arrangement of the chip pads are provided as an example, and the examples are not limited thereto.

In example embodiments, a plurality of openings may be formed in the sealing member 310 to expose the chip pads 210 of each of the semiconductor chips 200. The plurality of openings may include the plurality of trenches 320 that extend in a vertical direction (Z direction) from the first surface 312 of the sealing member 310 to the front surfaces 202 of the semiconductor chips 200.

In particular, the first trench 320a may extend in the vertical direction (Z direction) from the first surface 312 of the sealing member 310 to the front surface 202 of the first semiconductor chip 200a and may extend in the second direction (Y direction) in the peripheral region of the first semiconductor chip 200a to expose the chip pads 210a of the first semiconductor chip 200a. The second trench 320b may extend in the vertical direction (Z direction) from the first surface 312 of the sealing member 310 to the front surface 202 of the second semiconductor chip 200b and may extend in the second direction (Y direction) in the peripheral region of the second semiconductor chip 200b to expose the chip pads 210b of the second semiconductor chip 200b. The third trench 320c may extend in the vertical direction (Z direction) from the first surface 312 of the sealing member 310 to the front surface 202 of the third semiconductor chip 200c and may extend in the second direction (Y direction) in the peripheral region of the third semiconductor chip 200c to expose the chip pads 210c of the third semiconductor chip 200c. The fourth trench 320d may extend in the vertical direction (Z direction) from the first surface 312 of the sealing member 310 to the front surface 202 of the fourth semiconductor chip 200d and may extend in the second direction (Y direction) in the peripheral region of the fourth semiconductor chip 200d to expose the chip pads 210d of the fourth semiconductor chip 200d.

Each of the plurality of trenches 320 may extend in the second direction (Y direction). Each of the plurality of trenches 320 may have a length L in the second direction (Y direction) and a width D1 in the first direction (X direction) when viewed in bottom view of FIG. 3. The length L and the width D1 of each of the trenches 320 may be determined in consideration of a diameter of a capillary tip for forming the vertical conductive wires 400, a width of the chip pad, etc.

In example embodiments, the conductive wires 400 as a plurality of vertical conductive structures may extend vertically on the chip pads 210 of the first, second, third, and fourth semiconductor chips 200 within the trenches of the sealing member 310, respectively. When viewed from a bottom view, the conductive wires 400 may be positioned in an area where the plurality of semiconductor chips 200 are disposed.

In particular, the first conductive wires 400a may be conductive wires that extend from the chip pads 210a of the first semiconductor chip 200a to the first surface 312 of the sealing member 310 within the first trench 320a of the sealing member 310, respectively. The first conductive wires 400a may be spaced apart from an inner wall of the first trench 320a.

The second conductive wires 400b may be conductive wires that extend from the chip pads 210b of the second semiconductor chip 200b to the first surface 312 of the sealing member 310, respectively. The second conductive wires 400b may be spaced apart from an inner wall of the second trench 320b.

The third conductive wires 400c may be conductive wires that extend from the chip pads 210c of the third semiconductor chip 200c to the first surface 312 of the sealing member 310, respectively. The third conductive wires 400c may be spaced apart from an inner wall of the third trench 320c.

The fourth conductive wires 400d may be conductive wires that extend from the chip pads 210d of the fourth semiconductor chip 200d to the first surface 312 of the sealing member 310, respectively. The fourth conductive wires 400d may be spaced apart from an inner wall of the fourth trench 320d. The first, second, third and fourth conductive wires may be formed by a bonding wire process. For example, the conductive wire may include copper (Cu), gold (Au), aluminum (Al), etc.

As illustrated in FIG. 2, the conductive wires (e.g., the fourth conductive wire 400d) may include a wire body 401 extending in a vertical direction, a first bonding end portion 402 provided at a first end portion of the wire body 401 and bonded to the first chip pad 210d, and a second bonding end portion 404 provided at a second end portion opposite to the first end portion of the wire body 401. The wire body 401 may have a first diameter, and the second bonding end portion 404 may have a second diameter that is greater than the first diameter. For example, the width D1 of the trench 320 may be within a range of 70 μm to 120 μm. A diameter D2 of the wire body 401 may be within a range of 13 μm to 25 μm. A width (diameter) of the chip pad 210 may be within a range of 40 μm to 70 μm.

Referring to FIGS. 1 to 3, in example embodiments, the filling members 500 may be formed within the plurality of trenches 320 of the sealing member 310 to surround the conductive wires 400, respectively.

The first filling member 500a may be formed within the first trench 320a to surround the first conductive wires 400a. The first filling member 500a may fill a space between the first conductive wires 400a and the inner wall of the first trench 320a. An upper surface of the first filling member 500a may be exposed by the first surface 312 of the sealing member 310, and end portions of the first conductive wires 400a may be exposed by the upper surface of the first filling member 500a.

The second filling member 500b may be formed within the second trench 320b to surround the second conductive wires 400b. The second filling member 500b may fill a space between the second conductive wires 400b and the inner wall of the second trench 320b. An upper surface of the second filling member 500b may be exposed by the first surface 312 of the sealing member 310, and end portions of the second conductive wires 400b may be exposed by the upper surface of the second filling member 500b.

The third filling member 500c may be formed within the third trench 320c to surround the third conductive wires 400c. The third filling member 500c may fill a space between the third conductive wires 400c and the inner wall of the third trench 320c. An upper surface of the third filling member 500c may be exposed by the first surface 312 of the sealing member 310, and end portions of the third conductive wires 400c may be exposed by the upper surface of the third filling member 500c.

The fourth filling member 500d may be formed within the fourth trench 320d to surround the fourth conductive wires 400d. The fourth filling member 500d may fill a space between the fourth conductive wires 400d and the inner wall of the fourth trench 320d. An upper surface of the fourth filling member 500d may be exposed by the first surface 312 of the sealing member 310, and end portions of the fourth conductive wires 400d may be exposed by the upper surface of the fourth filling member 500d.

The sealing member 310 and the filling member 500 may include a thermosetting resin, for example, epoxy mold compound (EMC). The sealing member 310 and the filling member 500 may include fillers and an epoxy resin that acts as a binder for the fillers.

The sealing member 310 may have a first thermal expansion coefficient. The filling members 500 may have a second thermal expansion coefficient smaller than the first thermal expansion coefficient of the sealing member 310. The first thermal expansion coefficient may be within a range of 10 parts-per-million per degree centigrade (ppm/° C.) to 15 ppm/° C. The second thermal expansion coefficient may be within a range of 2.5 ppm/° C. to 6 ppm/° C. The filling members 500 may have a thermal conductivity smaller than that of the sealing member 310. The thermal conductivity of the molding member 310 may be within a range of 1.8 watt per meter-kelvin (W/m·K) to 3 W/m·K, and the thermal conductivity of the filling members 500 may be within a range of 1.5 W/m·K to 2 W/m·K.

The protective layer 300 may include a sealant film. The sealant film may include various forms of fillers and a resin to protect the semiconductor chips in the semiconductor package from an external environment. For example, the protective layer 300 may include an epoxy molding compound (EMC) film that is processed into a film form. The protective layer 300 may have a thickness of approximately several micrometers (μm) to several tens of μm.

The filling members 500 that fill the trenches 320 may have different properties from the sealing member 310, so that the mechanical behavior characteristics of the package may be improved. For example, the filling member 500 may have a relatively smaller thermal expansion coefficient than the sealing member 310, so that the bending characteristics of the package may be improved. Further, the filling member 500 may include the fillers with high thermal conductivity, so that the thermal stress concentrated at the joint end portion of the wire may be dispersed, to thereby improve thermal efficiency.

In example embodiments, external connection members 160 may be disposed on the lower surface of the redistribution wiring layer 100. For example, each of the external connection members 160 may include a pillar bump 162 formed on a lower bonding pad on the third redistribution wiring 132 exposed by the fourth lower insulating layer 140 and a solder bump 164 on the pillar bump 162. For example, the pillar bump may include a conductor (e.g., a zero-band gap material), such as copper (Cu), aluminum (Al), tin (Sn), nickel (Ni), gold (Au), platinum (Pt), an alloy thereof, and/or the like. The solder bump may include solder. The semiconductor package 10 may be configured to be mounted on a lower package, an interposer, a package substrate, etc. via the external connection members 160 to form a package-on-package (POP) device.

As mentioned above, the semiconductor package 10 may include the redistribution wiring layer 100 and the encapsulation structure ES stacked on the redistribution wiring layer 100. The encapsulation structure ES may include the sealing member 310, the plurality of semiconductor chips 200 arranged within the sealing member 310, the plurality of trenches 320 extending vertically from the first surface 312 of the sealing member 310 to the front surfaces 202 of the semiconductor chips 200 and exposing the chip pads 210, the conductive wires 400 extending on the chip pads 210 of the plurality of semiconductor chips 200 within the trenches 320 to be electrically connected to the redistribution wirings 102 of the redistribution wiring layer 100, and the filling members 500 within the plurality of trenches 320 to surround the conducive wires 400.

After forming the sealing member 310 covering the semiconductor chips 200, the trenches 320 may be formed in the sealing member 310 and the conductive wires 400 may be formed within the trenches 320, so that wire sagging, a phenomenon in which wires are tilted due to the flow of a molding material during the molding process, may be prevented (or mitigated), to thereby prevent (or reduce) wire short defects. Accordingly, the pitches and diameters of the wires may be formed to be smaller compared to a comparative package without the trenches 320.

Hereinafter, a method of manufacturing the semiconductor package in FIG. 1 will be explained.

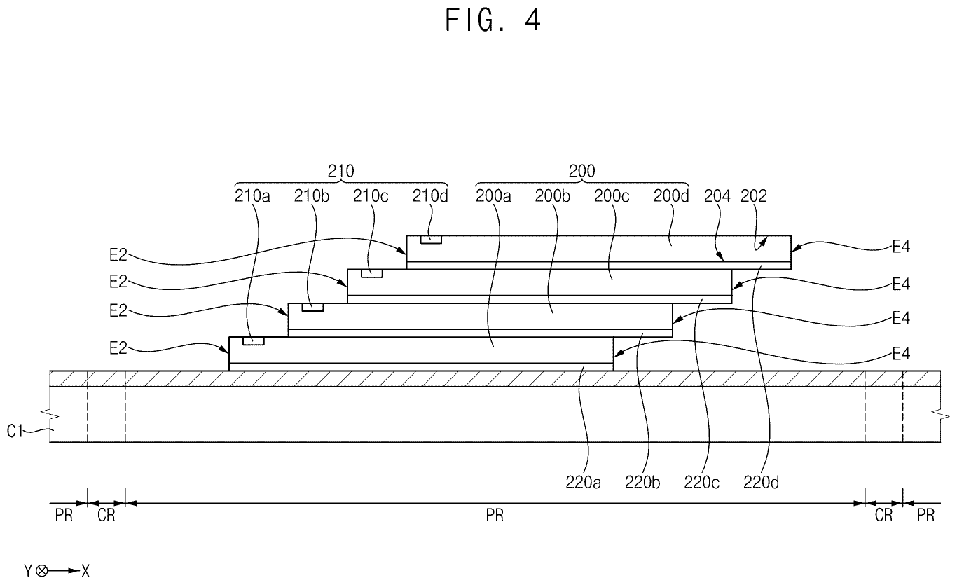

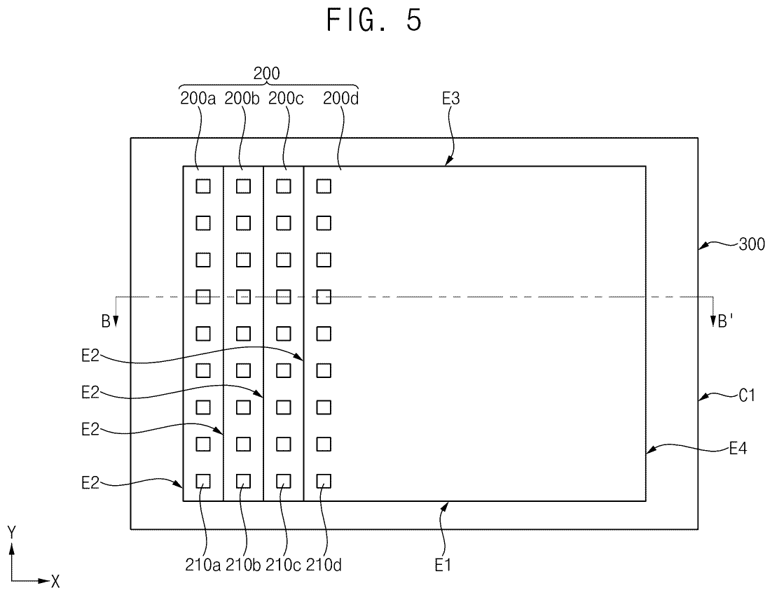

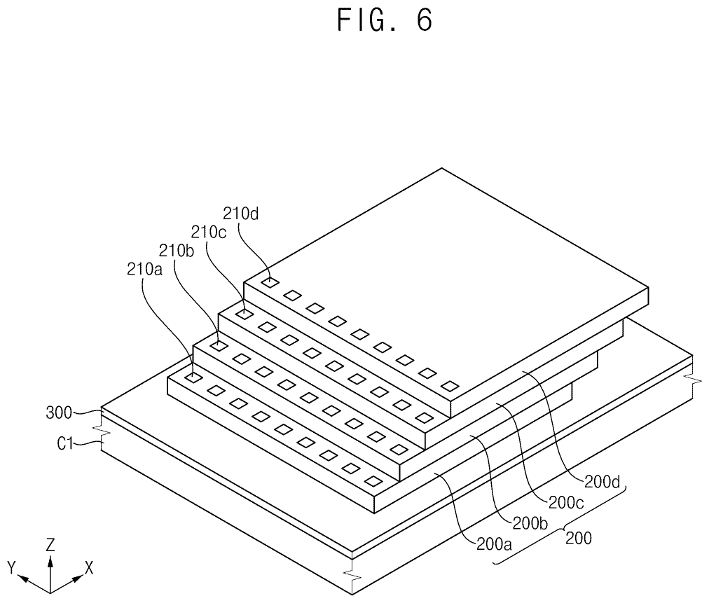

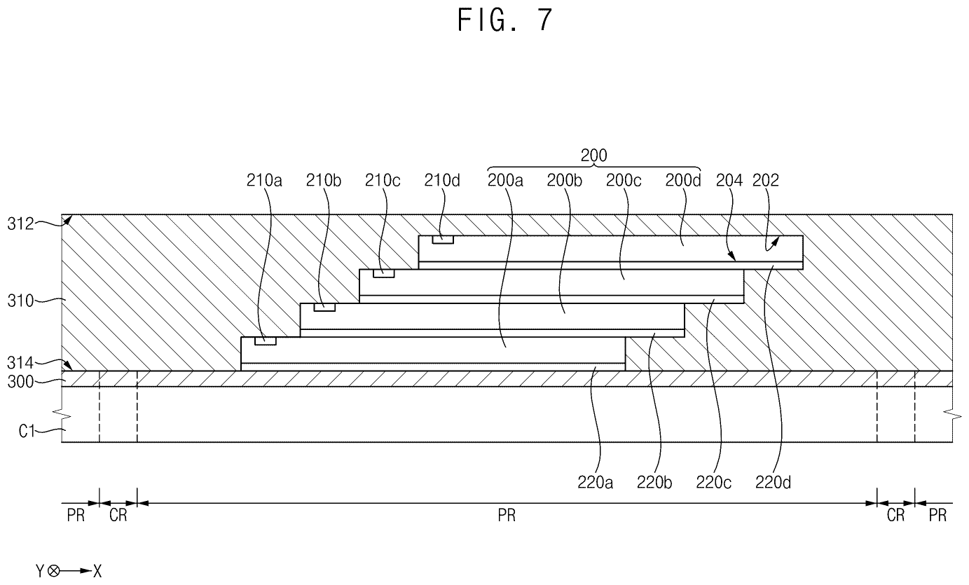

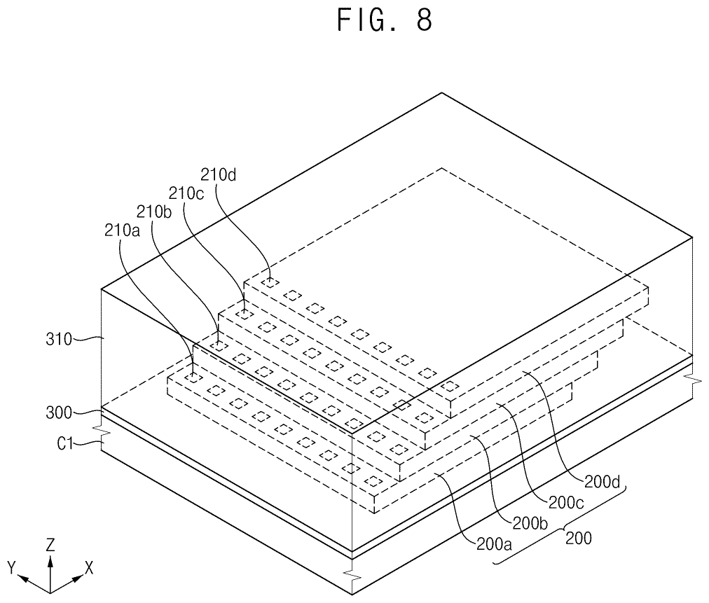

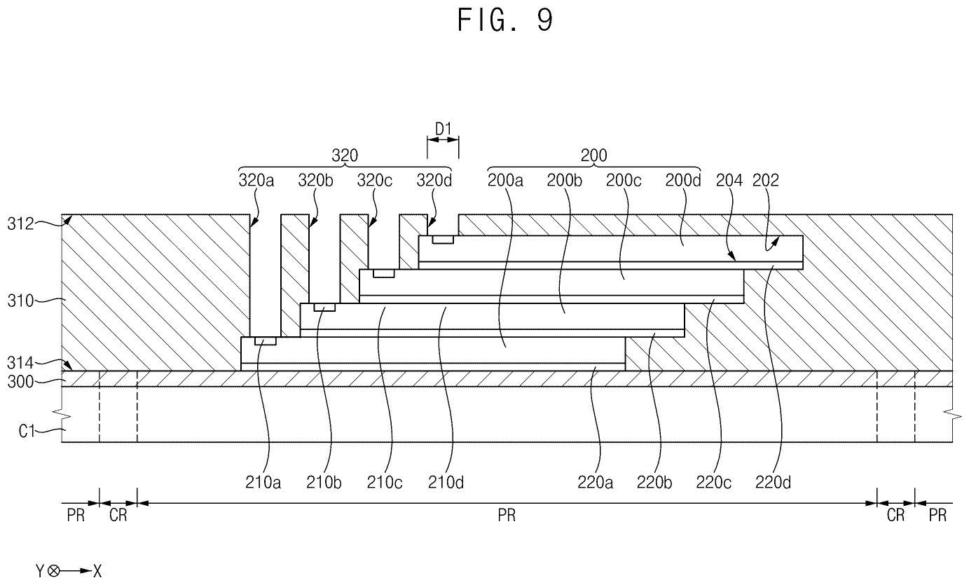

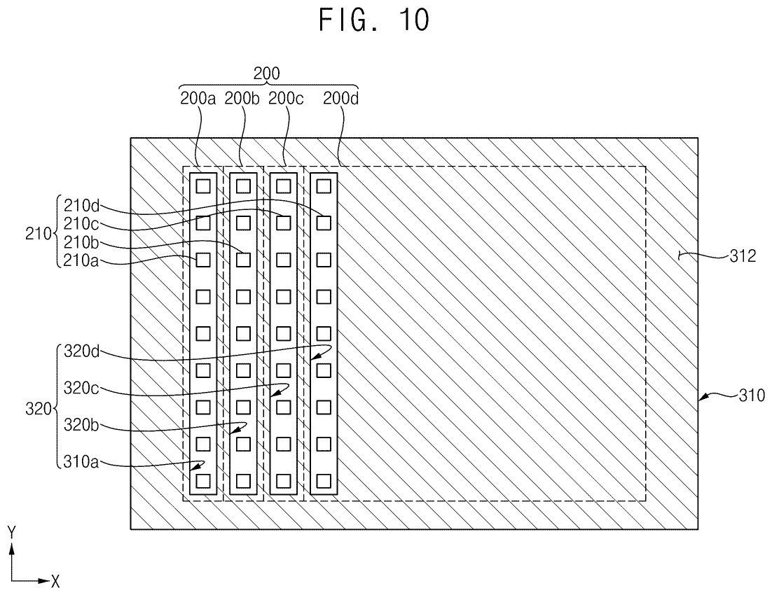

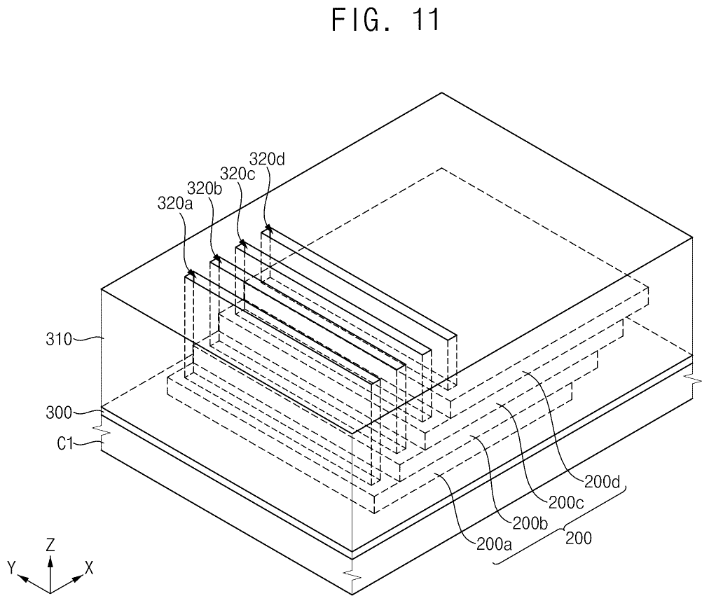

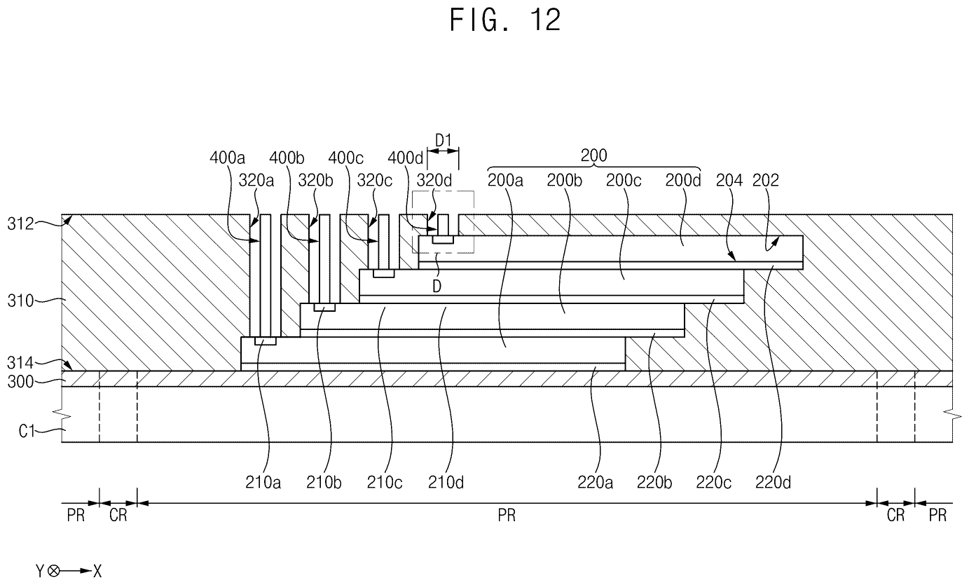

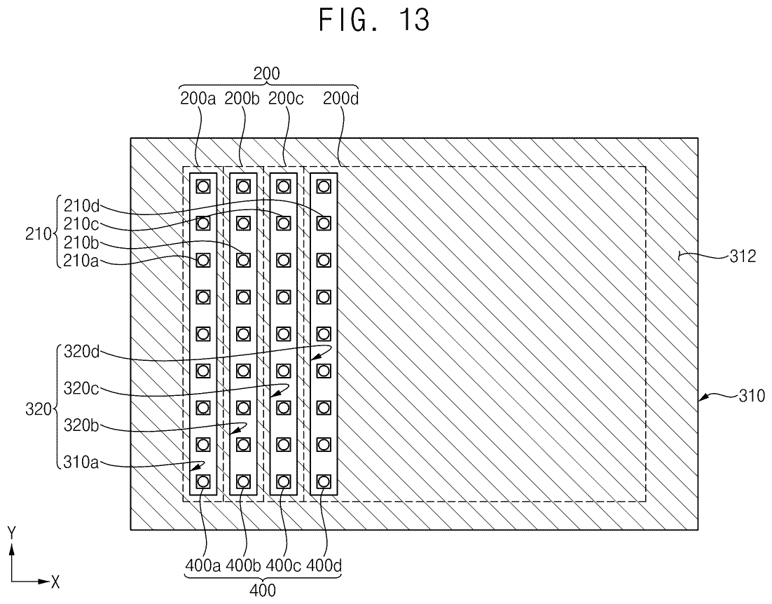

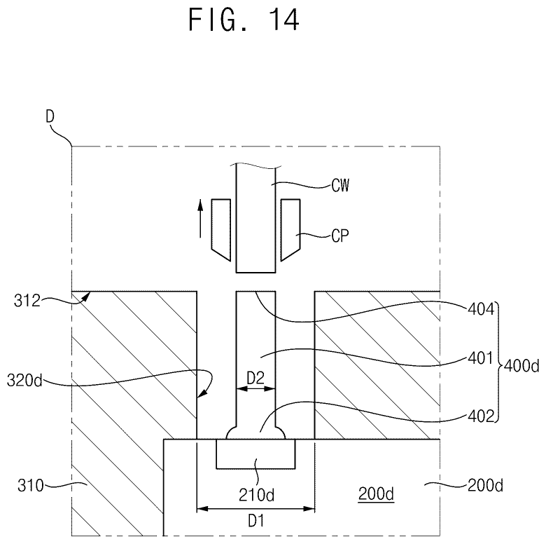

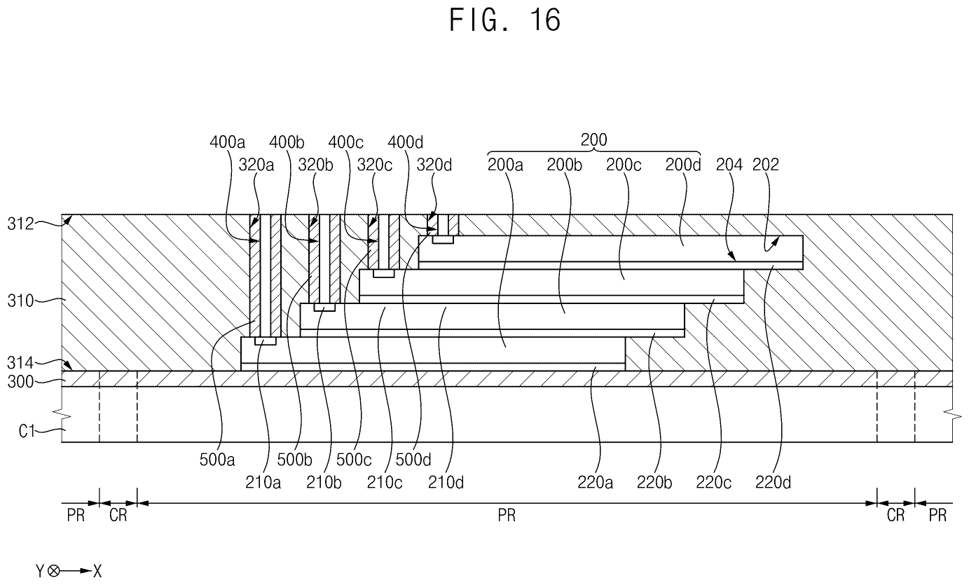

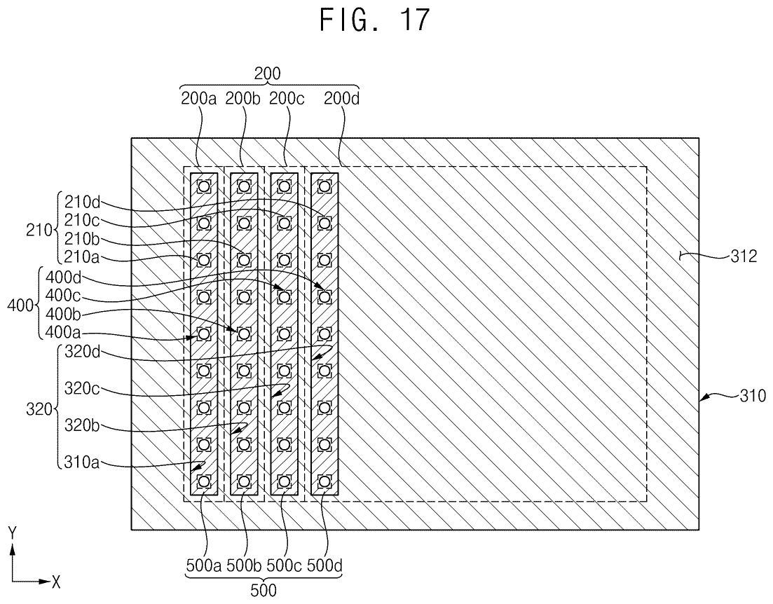

FIGS. 4 to 19 are views illustrating a method of manufacturing a semiconductor package in accordance with example embodiments. FIGS. 4, 7, 9, 12, 15, 16, 18 and 19 are cross-sectional views illustrating a method of manufacturing a semiconductor package in accordance with example embodiments. FIG. 5 is a plan view of FIG. 4. FIG. 6 is a perspective view of FIG. 4. FIG. 4 is a cross-sectional view taken along the line C-C′ in FIG. 5. FIG. 8 is a perspective view of FIG. 7. FIG. 10 is a plan view of FIG. 9. FIG. 11 is a perspective view of FIG. 9. FIG. 13 is a plan view of FIG. 12. FIG. 14 is an enlarged cross-sectional view illustrating a process of forming a vertical wire in portion ‘D’ in FIG. 12. FIG. 17 is a plan view of FIG. 16.

Referring to FIGS. 4 to 6, a protective layer 300 may be formed on a first carrier substrate C1, and a plurality of semiconductor chips 200 may be stacked on the protective layer 300.

In example embodiments, the first carrier substrate C1 may be provided as a base substrate on which the plurality of semiconductor chips 200 are stacked, a sealing member is formed and a redistribution wiring layer is formed. The first carrier substrate C1 may have a shape corresponding to a wafer on which semiconductor manufacturing processes are performed. For example, the first carrier substrate C1 may include a glass substrate, a silicon substrate, a non-metallic or metallic plate, etc.

The first carrier substrate C1 may include a package region PR in which the semiconductor chips are arranged and a cutting region CR surrounding the package region PR. As described below, the sealing member and the redistribution wiring layer formed on the first carrier substrate C1 may be cut along the cutting region CR that divides the plurality of package regions PR to be individualized.

In example embodiments, the protective layer 300 may be formed by attaching a sealant film on the first carrier substrate C1, e.g., by a lamination process. The sealant film may include various forms of fillers and a resin to protect the semiconductor chips in the semiconductor package from an external environment. For example, the protective layer 300 may include an epoxy molding compound (EMC) film that is processed into a film form. The protective layer 300 may have a thickness of approximately several micrometers (μm) to several tens of μm.

In example embodiments, four semiconductor chips 200a, 200b, 200c and 200d may be sequentially stacked on the first carrier substrate C1. Individual semiconductor chips diced from a wafer by a dicing process may be provided as the semiconductor chips.

The semiconductor chips 200a, 200b, 200c and 200d may be sequentially attached onto the protective layer 300 on the first carrier substrate C1 using adhesive films 220a, 220b, 220c, and 220d. The semiconductor chips 200a, 200b, 200c and 200d may be sequentially attached to the protective layer 300 using the adhesive films such as a die attach film (DAF) by a die attach process. For example, a thickness of the semiconductor chip may be within a range of 40 μm to 110 μm. A thickness of the adhesive film may be within the range of 10 μm to 60 μm.

The semiconductor chips 200a, 200b, 200c, and 200d may be arranged such that a backside surface 204 opposite to a front surface 322 on which chip pads 210a, 210b, 210c, and 210d are formed, that is, an inactive surface faces the first carrier substrate C1. Each of the semiconductor chips 200a, 200b, 200c, and 200d may have a quadrangular shape having four sides when viewed in plan view. A first side surface E1 and a third side surface E3 of each of the semiconductor chips may be arranged to be parallel to a first direction (X direction), and a second side surface E2 and a fourth side surface E4 of each of the semiconductor chips may be arranged to be parallel to a second direction (Y direction) perpendicular to the first direction. The chip pads 210 may be disposed in a peripheral region along one side of each of the semiconductor chips 200a, 200b, 200c and 200d. The chip pads 210 may be arranged to be spaced apart from each other in the second direction (Y direction) on the front surface 202 of each of the semiconductor chips 200a, 200b, 200c, and 200d.

In example embodiments, the semiconductor chips 200a, 200b, 200c and 200d may be stacked in a cascade structure on the first carrier substrate C1. The second semiconductor chip 200b may be aligned with an offset in a first horizontal direction (X direction) on the first semiconductor chip 200a. The second semiconductor chip 200b may be offset aligned in the first horizontal direction such that the chip pads 210a of the first semiconductor chip 200a are exposed from the second semiconductor chip 200b. The third semiconductor chip 200c may be aligned with an offset in the first horizontal direction on the second semiconductor chip 200b. The third semiconductor chip 200c may be offset aligned in the first horizontal direction such that the chip pads 210b of the second semiconductor chip 200b are exposed from the third semiconductor chip 200c. The fourth semiconductor chip 200d may be aligned with an offset in a direction opposite to the first horizontal direction on the third semiconductor chip 200c. The fourth semiconductor chip 200d may be offset aligned in the first horizontal direction such that the chip pads 210c of the third semiconductor chip 200c are exposed from the fourth semiconductor chip 200d.

Each of the first, second, and third semiconductor chips 200a, 200b, and 200c has an overhang portion protruding from one side of each of the overlying second, third, and fourth semiconductor chips 200b, 200c, and 200d. When viewed from the plan view, the chip pads 210a of the first semiconductor chip 200a may be arranged on an upper surface (that is, the front surface 202) of the overhang portion protruding from one side surface E2 of the second semiconductor chips 200b to be spaced apart from each other along a second horizontal direction (Y direction) perpendicular to the first horizontal direction. When viewed from the plan view, the chip pads 210b of the second semiconductor chip 200b may be arranged on an upper surface (that is, the front surface 202) of the overhang portion protruding from one side surface E2 of the third semiconductor chips 200c to be spaced apart from each other along the second horizontal direction. When viewed from the plan view, the chip pads 210c of the third semiconductor chip 200c may be arranged on an upper surface (that is, the front surface 202) of the overhang portion protruding from one side surface E2 of the fourth semiconductor chip 200d to be spaced apart from each other along the second horizontal direction.

The semiconductor chip may include a memory chip including a memory circuits. For example, the semiconductor chip may include volatile memory devices such as SRAM devices and/or DRAM devices, and/or non-volatile memory devices such as flash memory devices, PRAM devices, MRAM devices or RRAM devices.

It will be understood that the number, size, arrangement, etc. of the semiconductor chips are provided as an example, and the examples are not limited thereto. Also, although only a few chip pads are illustrated in the figures, it will be understood that the structure, shape, and arrangement of the chip pads are provided as an example, and the examples are not limited thereto.

Referring to FIGS. 7 and 8, a sealing member 310 may be formed on the protective layer 300 on the first carrier substrate C1 to cover the plurality of semiconductor chips 200.

In example embodiments, a sealing material may be formed on an upper surface of the protective layer 300 to cover the plurality of semiconductor chips 200, and an upper portion of the sealing material may be partially removed to form the sealing member 310 having a desired height. The sealing member 310 may be formed to completely cover the plurality of semiconductor chips 200. The sealing member 310 may have a first surface 312 and a second surface 314 opposite to the first surface 312. The second surface 314 of the sealing member 310 may be in contact with the protective layer 300.

For example, the sealing member 310 may be formed on the first carrier substrate C1 by a transfer molding apparatus. The sealing member 310 may include a thermosetting resin, for example, epoxy mold compound (EMC). The sealing member 310 may include fillers and an epoxy resin that acts as a binder for the fillers. The sealing member 310 may have a first thermal expansion coefficient. The first thermal expansion coefficient may be within a range of 10 ppm/° C. to 15 ppm/° C.

Referring to FIGS. 9 to 11, a plurality of openings may be formed in the sealing member 310 to expose the chip pads 210 of each of the semiconductor chips 200. The plurality of openings may include a plurality of trenches 320 that extend in a vertical direction (Z direction) from the first surface 312 of the sealing member 310 to the front surfaces 202 of the semiconductor chips 200.

In example embodiments, a photoresist pattern having trench openings for exposing the chip pads 210 of each of the semiconductor chips 200 may be formed on the first surface 312 of the sealing member 310, and the photoresist pattern may be used as an etching mask to partially remove the sealing member 310 until the chip pads 210 of the semiconductor chips 200 are exposed, to form the plurality of trenches 320. The plurality of trenches 320 may be formed by partially removing the sealing member 310 by an etching process. However, the examples are not limited thereto, and for example, the plurality of trenches 320 may be formed by partially removing the sealing member 310 by a laser processing process.

Each of the plurality of trenches 320 may extend in the second direction (Y direction). Each of the plurality of trenches 320 may have a length L in the second direction (Y direction) and a width D1 in the first direction (X direction) when viewed in a plan view. The length L and the width D1 of each of the trenches 320 may be determined in consideration of a diameter of a capillary tip for forming vertical wires as described below, a width of the chip pad, etc. For example, the width (diameter) of the chip pad 210 may be within a range of 40 μm to 70 μm, and the width D1 of the trench 320 may be within a range of 70 μm to 120 μm.

In example embodiments, the first trench 320a may extend in the vertical direction (Z direction) from the first surface 312 of the sealing member 310 to the front surface 202 of the first semiconductor chip 200a and may extend in the second direction (Y direction) in the peripheral region of the first semiconductor chip 200a to expose the chip pads 210a of the first semiconductor chip 200a. The second trench 320b may extend in the vertical direction (Z direction) from the first surface 312 of the sealing member 310 to the front surface 202 of the second semiconductor chip 200b and may extend in the second direction (Y direction) in the peripheral region of the second semiconductor chip 200b to expose the chip pads 210b of the second semiconductor chip 200b. The third trench 320c may extend in the vertical direction (Z direction) from the first surface 312 of the sealing member 310 to the front surface 202 of the third semiconductor chip 200c and may extend in the second direction (Y direction) in the peripheral region of the third semiconductor chip 200c to expose the chip pads 210c of the third semiconductor chip 200c. The fourth trench 320d may extend in the vertical direction (Z direction) from the first surface 312 of the sealing member 310 to the front surface 202 of the fourth semiconductor chip 200d and may extend in the second direction (Y direction) in the peripheral region of the fourth semiconductor chip 200d to expose the chip pads 210d of the fourth semiconductor chip 200d.

Referring to FIGS. 12 to 14, conductive wires 400 as a plurality of vertical conductive structures may be formed on the plurality of semiconductor chips 200a, 200b, 200c, and 200d within the trenches 320 of the sealing member 310. The conductive wires 400a, 400b, 400c, and 400d may be formed on the chip pads 210a, 210b, 210c, and 210d of the first, second, third, and fourth semiconductor chips 200a, 200b, 200c, and 200d, respectively.

In example embodiments, the conductive wires 400 may be formed by a bonding wire process. The conductive wires 400 may be bonding wires formed by the bonding wire process.

As illustrated in FIG. 14, after one end portion of a wire CW drawn from a capillary CP of a wire bonding apparatus is bonded to the chip pad 210d of the fourth semiconductor chip 200d, the capillary CP may move in an upward vertical direction to withdraw the wire. Then, when the wire is extended by a predetermined length, a portion of the wire may be cut to form the conductive wire 400d.

Thus, the conductive wire 400d may include a wire body 401 extending in the vertical direction, a first bonding end portion 402 provided at a first end portion of the wire body 401 and bonded to the chip pad 210d, and a second bonding end portion 404 provided at a second end portion opposite to the first end portion of the wire body 401. A diameter of the wire body 401 may be within a range of 13 μm to 25 μm.

The first conductive wires 400a may extend vertically (in the Z direction) from the chip pads 210a of the first semiconductor chip 200a within the first trench 320a of the sealing member 310, respectively. The first conductive wires 400a may be spaced apart from an inner wall of the first trench 320a.

The second conductive wires 400b may extend vertically (in the Z direction) from the chip pads 210b of the second semiconductor chip 200b within the second trench 320b of the sealing member 310. The second conductive wires 400b may be spaced apart from an inner wall of the second trench 320b.

The third conductive wires 400c may extend vertically (in the Z direction) from the chip pads 210c of the third semiconductor chip 200c within the third trench 320c of the sealing member 310. The third conductive wires 400c may be spaced apart from an inner wall of the third trench 320c.

The fourth conductive wires 400d may extend vertically (in the Z direction) from the chip pads 210d of the fourth semiconductor chip 200d within the fourth trench 320d of the sealing member 310. The fourth conductive wires 400d may be spaced apart from an inner wall of the fourth trench 320d.

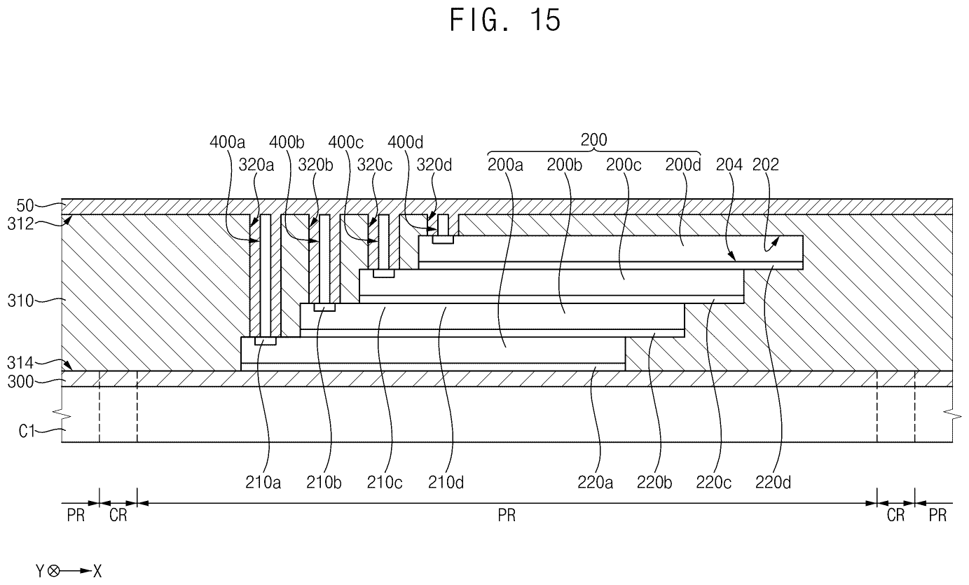

Referring to FIGS. 15 to 17, filling members 500 may be formed within the plurality of trenches 320 of the sealing member 310 to surround the conductive wires 400, respectively.

As illustrated in FIG. 15, a second sealing material may be formed on the first surface 312 of the sealing member 310 and may fill the plurality of trenches 320. The second sealing material may be formed by an underfill process. A liquid underfill solution may be applied onto the first surface 312 of the sealing member 310 using a dispenser nozzle, and then cured to form the filling member. The underfill solution may have a relatively low viscosity. The second sealing material may include a thermosetting resin, for example, epoxy mold compound (EMC). The second sealing material may include fillers and an epoxy resin that acts as a binder for the fillers.

As illustrated in FIGS. 16 and 17, an upper portion of the second sealing material may be at least partially removed to expose the first surface 312 of the sealing member 310 and the end portions (second bonding end portions 404) of the conductive wires 400, to form the filling members 500 within the plurality of trenches 320, respectively.

The first filling member 500a may be formed to surround the first conductive wires 400a within the first trench 320a. The first filling member 500a may fill a space between the first conductive wires 400a and the inner wall of the first trench 320a. An upper surface of the first filling member 500a may be exposed by the first surface 312 of the sealing member 310, and end portions of the first conductive wires 400a may be exposed by the upper surface of the first filling member 500a.

The second filling member 500b may be formed to surround the second conductive wires 400b within the second trench 320b. The second filling member 500b may fill a space between the second conductive wires 400b and the inner wall of the second trench 320b. An upper surface of the second filling member 500b may be exposed by the first surface 312 of the sealing member 310, and end portions of the second conductive wires 400b may be exposed by the upper surface of the second filling member 500b.

The third filling member 500c may be formed to surround the third conductive wires 400c within the third trench 320c. The third filling member 500c may fill a space between the third conductive wires 400c and the inner wall of the third trench 320c. An upper surface of the third filling member 500c may be exposed by the first surface 312 of the sealing member 310, and end portions of the third conductive wires 400c may be exposed by the upper surface of the third filling member 500c.

The fourth filling member 500d may be formed to surround the fourth conductive wires 400d within the fourth trench 320d. The fourth filling member 500d may fill a space between the fourth conductive wires 400d and the inner wall of the fourth trench 320d. An upper surface of the fourth filling member 500d may be exposed by the first surface 312 of the sealing member 310, and end portions of the fourth conductive wires 400d may be exposed by the upper surface of the fourth filling member 500d.

The filling members 500 may have a second thermal expansion coefficient smaller than the first thermal expansion coefficient of the sealing member 310. The second thermal expansion coefficient may be within a range of 2.5 ppm/° C. to 6 ppm/° C. The filling members 500 may have relatively large thermal conductivity. The filling members 500 may have a thermal conductivity smaller than that of the sealing member 310. The thermal conductivity of the molding member 310 may be within a range of 1.8 W/m·K to 3 W/m·K, and the thermal conductivity of the filling members 500 may be within a range of 1.5 W/m·K to 2 W/m·K.

After forming the molding member 310, the trenches 320 may be formed in the molding member 310 and the conductive wires 400 may be formed in the trenches 320, so that the wires may be prevented (or mitigated) from being tilted by the flow of the molding material during the molding process (wire sagging). Accordingly, the pitches and diameters of the wires may be formed to be smaller. In addition, the filling members 500 that fill the trenches 320 may have different properties from the sealing member 310, so that the mechanical behavior characteristics of the package may be improved. For example, the filling member 500 may have a relatively smaller thermal expansion coefficient than the sealing member 310, so that the bending characteristics of the package may be improved. Further, the filling member 500 may include the fillers with high thermal conductivity, so that the thermal stress concentrated at the joint end portion of the wire may be dispersed, to thereby improve thermal efficiency.

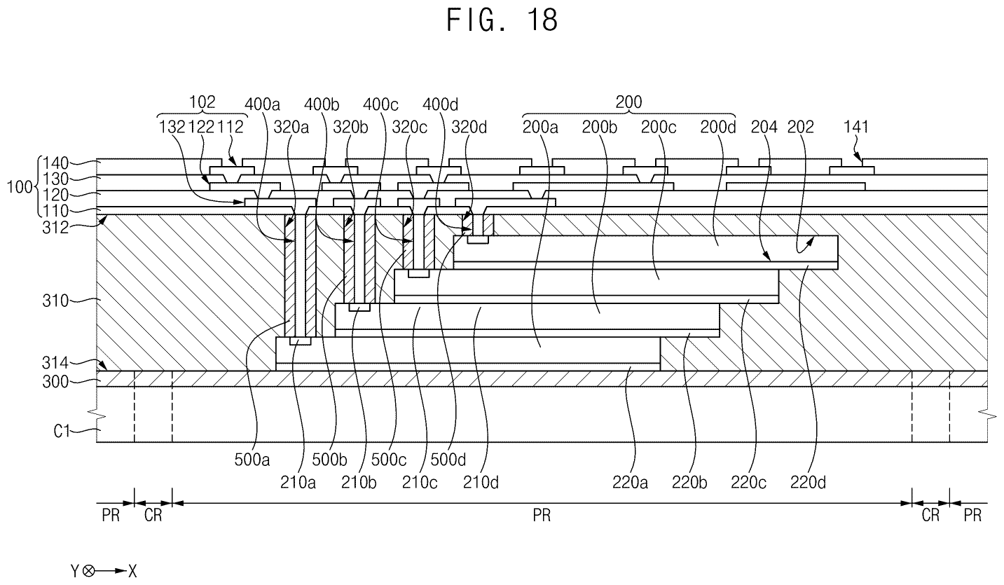

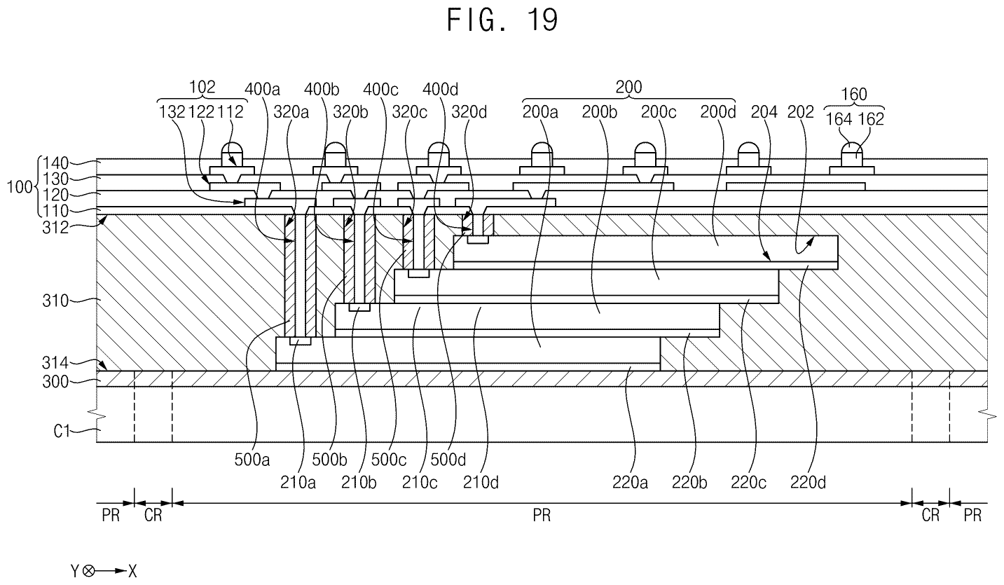

Referring to FIGS. 18 and 19, a redistribution wiring layer 100 may be formed on the first surface 312 of the sealing member 310, and a plurality of external connection members 160 may be formed on the redistribution wiring layer 100.

As illustrated in FIG. 18, the redistribution wiring layer 100 having redistribution wirings 102 electrically connected to the conductive wires 400 may be formed on the first surface 312 of the sealing member 310.

In example embodiments, after a first lower insulating layer 110 is formed on the first surface 312 of the sealing member 310 and upper surfaces of the filling members 500, the first lower insulating layer 110 may be patterned to form first openings. The first openings may expose the end portions of the conductive wires 400 (e.g., the second bonding end portions 404) respectively. The first lower insulating layer 110 may include an insulator, such as a polymer, a dielectric layer, etc. The first lower insulating layer 110 may be formed by a vapor deposition process, a spin coating process, or the like.

Then, after a seed layer is formed on the exposed end portions of the conductive wires 400 and in the first openings, the seed layer may be patterned and an electrolytic plating process may be performed to form first redistribution wirings 112. Accordingly, at least portions of the first redistribution wirings 112 may be electrically connected to the conductive wires 400 through the first openings. The first redistribution wirings may include aluminum (Al), copper (Cu), tin (Sn), nickel (Ni), gold (Au), platinum (Pt), or an alloy thereof.

Similarly, after forming a second lower insulating layer 120 on the first lower insulating layer 110, the second lower insulating layer 120 may be patterned to form second openings that expose the first redistribution wirings 112. Then, second redistribution wirings 122 may be formed on the second lower insulating layer 120 to be electrically connected to the first redistribution wirings 112 through the second openings.

Similarly, after forming a third lower insulating layer 130 on the second lower insulating layer 120, the third lower insulating layer 130 may be patterned to form third openings that expose the second redistribution wirings 122, respectively. Then, third redistribution wirings 132 may be formed on the third lower insulating layer 130 to be electrically connected to the second redistribution wirings 122 through the third openings.

Then, a fourth lower insulating layer 140 may be formed on the third lower insulating layer 130 to cover the third redistribution wirings 132. The fourth lower insulating layer 140 may serve as a passivation layer. Then, the fourth lower insulating layer 140 may be partially removed by a via formation process to form openings 141 that expose portions of the third redistribution wirings 132. A lower bonding pad (not illustrated) such as UBM may be formed on the portion of the third redistribution wiring 132 exposed by the fourth lower insulating layer 140 through a plating process.

Thus, the redistribution wiring layer 100 having the redistribution wirings 102 as a front redistribution layer (FRDL) may be formed on the sealing member 310. The redistribution wiring layer 100 may include the stacked first to fourth lower insulating layers 110, 120, 130, 140 and the redistribution wirings 102 in the first to fourth lower insulating layer 110, 120, 130, 140. The redistribution wirings 102 may include the first, second, and third redistribution wirings 112, 122, 132.

It will be understood that the number, size, arrangement, etc. of the insulating layers and the redistribution wirings of the redistribution wiring layer are provided as an example, and the examples are not limited thereto.

As illustrated in FIG. 19, the external connection members 160 electrically connected to the redistribution wirings 102, respectively, may be formed on the redistribution wiring layer 100.

In example embodiments, a seed layer and a photoresist layer may be formed on the fourth lower insulating layer 140, and an exposure process may be performed to form a photoresist pattern having openings that expose bump regions. Then, after filling the openings of the photoresist pattern with a conductive material, the photoresist pattern may be removed, and a reflow process may be performed to form the external connection members 160. Alternatively, the conductive bumps may be formed by a screen printing process, a deposition process, or the like.

For example, a pillar bump 162 may be formed on the lower bonding pad on the third redistribution wiring 132 exposed by the fourth lower insulating layer 140, and a solder bump 164 may be formed on the pillar bump 162. Accordingly, each of the external connection members 160 may include the pillar bump 162 and the solder bump 164 on the pillar bump 162. For example, the pillar bump may include a conductor, such as copper (Cu), aluminum (Al), tin (Sn), nickel (Ni), gold (Au), platinum (Pt), an alloy thereof, and/or the like. The solder bump may include solder.

Then, the redistribution wiring layer 100, the sealing member 310 and the protective layer 300 may be cut along the cutting region to complete a semiconductor package 10 of FIG. 1.

In example embodiments, the first carrier substrate C1 may be separated and removed from the protective layer 300, a dicing tape may be attached on the protective layer 300, and the dicing tape may be used to attach the structure to a lower surface of a ring frame. The redistribution wiring layer 100, the sealing member 310 and the protective layer 300 may be preliminarily cut along the cutting region CR, and the dicing tape may be expanded to separate the semiconductor packages 10 individually.

The redistribution wiring layer 100, the sealing member 310 and the protective layer 300 may be cut by a sawing process to form the semiconductor package 10 including the redistribution wiring layer 100 and an encapsulation structure ES stacked on the redistribution wiring layer 100. Accordingly, an outer side surface of the redistribution wiring layer 100 may be positioned on the same plane as an outer side surface of the sealing member 310. Additionally, the outer side surface of the sealing member 310 may be positioned on the same plane as an outer side surface of the protective layer 300.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a redistribution wiring layer having redistribution wirings;
a sealing member on the redistribution wiring layer, the sealing member having a first surface in contact with the redistribution wiring layer and a second surface opposite to the first surface;
a plurality of semiconductor chips within the sealing member; the plurality of semiconductor chips stacked such that a front surface of each of the semiconductor chips faces the redistribution wiring layer, the front surface of each of the semiconductor chips including chip pads;
a plurality of trenches defined by the sealing member, the plurality of trenches extending in a vertical direction from the first surface of the sealing member to the front surfaces of the semiconductor chips such that the plurality of trenches expose the chip pads;
a plurality of conductive wires within the plurality of trenches and extending in the vertical direction, the plurality of conductive wires electrically connecting the chip pads to the redistribution wirings; and
filling members within the plurality of trenches and surrounding the conductive wires.

2. The semiconductor package of claim 1, wherein the chip pads of each of the plurality of semiconductor chips are spaced apart from each other in a first direction, and the plurality of trenches extend in the first direction to expose the chip pads.

3. The semiconductor package of claim 2, wherein, when viewed in a plan view, each of the plurality of trenches has a length in the first direction and a width in a second direction perpendicular to the first direction, and the width in the second direction is within a range of 70 micrometers (μm) to 120 μm.

4. The semiconductor package of claim 1, wherein each of the conductive wires has a diameter within a range of 13 micrometers (μm) to 25 μm.

5. The semiconductor package of claim 1, wherein
the sealing member has a first thermal expansion coefficient, and
each of the filling members have a second thermal expansion coefficient greater than the first thermal expansion coefficient.

6. The semiconductor package of claim 1, wherein each of the conductive wires includes:
a wire body extending in the vertical direction;
a first bonding end portion at a first end portion of the wire body and exposed from the first surface of the sealing member; and
a second bonding end portion at a second end portion of the wire body and bonded to a corresponding one of the chip pads.

7. The semiconductor package of claim 6, wherein the conductive wire comprises at least one of copper (Cu), gold (Au), or aluminum (Al).

8. The semiconductor package of claim 1, further comprising:
a protective layer on the second surface of the sealing member.

9. The semiconductor package of claim 8, wherein the plurality of semiconductor chips include first, second, third and fourth semiconductor chips that are stacked in a cascade manner from a lower surface of the protective layer,
each of the first, second and third semiconductor chips includes an overhang portion that protrudes from one side of the underlying second, third and fourth semiconductor chips, and
the chip pads of each of the first, second and third semiconductor chips are provided on a lower surface of the overhang portion.

10. The semiconductor package of claim 1, further comprising:
external connection members on an outer surface of the redistribution wiring layer, the external connection members electrically connected to the redistribution wirings.

11. A semiconductor package, comprising:
a redistribution wiring layer having redistribution wirings;
an encapsulation structure on the redistribution wiring layer; and
outer connection members on an outer surface of the redistribution wiring layer, the outer connection members electrically connected to the redistribution wirings,
wherein the encapsulation structure includes
a sealing member having a first surface in contact with the redistribution wiring layer and a second surface opposite to the first surface,
a plurality of semiconductor chips within the sealing member, the plurality of semiconductor chips sequentially stacked such that a front surface of each of the plurality of semiconductor chips faces the redistribution wiring layer, the front surface of each of the semiconductor chips including chip pads,
a plurality of trenches defined by the sealing member, the plurality of trenches extending in a vertical direction from the first surface of the sealing member to the front surfaces of the semiconductor chips such that plurality of trenches expose the chip pads,
a plurality of conductive wires within the plurality of trenches and extending in the vertical direction, the plurality of conductive wires electrically connecting the chip pads to the redistribution wirings, and
filling members within the plurality of trenches and surrounding the conductive wires.

12. The semiconductor package of claim 11, wherein
the chip pads of each of the plurality of semiconductor chips are spaced apart from each other in a first direction, perpendicular to the vertical direction, and the plurality of trenches each extend in the first direction to expose respective chip pads of the chip pads.

13. The semiconductor package of claim 12, wherein, when viewed in a plan view, each of the plurality of trenches has a length in the first direction and a width in a second direction perpendicular to the first direction, and the width in the second direction is within a range of 70 micrometers (μm) to 120 μm.

14. The semiconductor package of claim 11, wherein each of the conductive wires has a diameter within a range of 13 micrometers (μm) to 25 μm.

15. The semiconductor package of claim 11, wherein
the sealing member has a first thermal expansion coefficient, and
each of the filling members have a second thermal expansion coefficient greater than the first thermal expansion coefficient.

16. The semiconductor package of claim 11, wherein each of the conductive wires includes:
a wire body extending in the vertical direction;
a first bonding end portion at a first end portion of the wire body and exposed from the first surface of the sealing member; and
a second bonding end portion at a second end portion of the wire body and bonded to a corresponding one of the chip pads.

17. The semiconductor package of claim 16, wherein the conductive wire comprises at least one of copper (Cu), gold (Au), or aluminum (Al).

18. The semiconductor package of claim 11, further comprising:
a protective layer on the second surface of the sealing member.

19. The semiconductor package of claim 18, wherein the plurality of semiconductor chips include first, second, third and fourth semiconductor chips stacked in a cascade manner from a lower surface of the protective layer,
each of the first, second and third semiconductor chips includes an overhang portion protruding from one side of the underlying second, third and fourth semiconductor chips located underneath, and
the chip pads of each of the first, second and third semiconductor chips are provided on a lower surface of the overhang portion.

20. A semiconductor package, comprising:
a redistribution wiring layer having redistribution wirings stacked in at least two layers and external connection members on an outer surface of the redistribution wiring layer, the external connection members electrically connected to the redistribution wirings; and
an encapsulation structure stacked on the redistribution wiring layer, the encapsulation structure including
a sealing member having a first surface in contact with the redistribution wiring layer and a second surface opposite to the first surface,
a plurality of semiconductor chips within the sealing member, with a horizontal offset relative to each other the plurality of semiconductor chips sequentially stacked such that a front surface of each of the semiconductor chips faces the redistribution wiring layer, the front surface of each of the semiconductor chips including chip pads,
a plurality of trenches defined by the sealing member, the plurality of trenches extending in a vertical direction from the first surface of the sealing member to the front surfaces of the semiconductor chips such that the plurality of trenches expose the chip pads,
a plurality of conductive wires within the plurality of trenches and extending in the vertical direction, the plurality of conductive wires electrically connecting the chip pads to the redistribution wirings, and
filling members within the plurality of trenches and surrounding the conductive wires.
